(19) United States
(12) Patent Application Publication
(10) Pub. No.: US 2010/0323127 A1
(43) Pub. Date: Dec. 23, 2010

(54) ATMOSPHERIC PRESSURE PLASMA ENHANCED CHEMICAL VAPOR DEPOSITION PROCESS

(76) Inventors: Christina Ann Rhoton, Bently, MI (US); John Matthew Warakomski, Midland, MI (US)

Correspondence Address: The Dow Chemical Company, P.O. BOX 1967, 2040 Dow Center, Midland, MI, 48641, US

(21) Appl. No.: 12/666,307

(22) PCT Filed: Jul. 15, 2008
(86) PCT No.: PCT/US08/70081

§ 371 Date: Dec. 23, 2009

Related U.S. Application Data
(60) Provisional application No. 60/962,508, filed on Jul. 30, 2007.

(30) Foreign Application Priority Data
Sep. 19, 2007 (US) 11901849

(51) Int. Cl. C23C 16/40; C23C 16/50

(52) U.S. Cl. 427/579

(57) ABSTRACT

A process for depositing a film coating on an exposed surface of a substrate by the steps of: (a) providing a substrate having at least one exposed surface; and (b) flowing a gaseous mixture into an atmospheric pressure plasma that is in contact with at least one exposed surface of said substrate to form a plasma enhanced chemical vapor deposition coating on the substrate, the gaseous mixture containing an oxidizing gas and a precursor selected from the group consisting of: a vinylalkoxysilane, a vinylalkylsilane, a vinylalkylalkoxysilane, an allyalkoxysilane, an allylalkylsilane, an allylalkylalkoxysilane, an alkenylalkoxysilane, an alkenylalkylsilane, and an alkenylalkylalkoxysilane, the oxygen content of the gaseous mixture being greater than ten percent by volume.

### BACKGROUND OF THE INVENTION

The instant invention is in the field of plasma enhanced chemical vapor deposition (PECVD) methods and more specifically PECVD conducted at or near atmospheric pressure using specific precursors.

The use of PECVD techniques to coat an object with, for example, a silicon oxide layer and/or a polyorganosiloxane layer is well known as described, for example, in WO 2004/044039 A2. PECVD can be conducted in a reduced pressure chamber or in the open at or near atmospheric pressure. PECVD conducted at or near atmospheric pressure in the open has the advantage of lower equipment costs and more convenient manipulation of the substrates to be coated. Yamada et al., USPP 2003/0189403 disclosed an atmospheric pressure PECVD system for coating flexible substrates by flowing a gaseous mixture containing, among others, the precursor tetramethyldisiloxane, vinyltrimethoxysilane or vinyltriethoxysilane into a plasma in the vicinity of one surface of the flexible substrate. However Yamada et al. did not report any difference in the physical properties of the coatings produced from these precursors. It would be an advance in the art if an atmospheric pressure PECVD process were discovered that provided an increased deposition rate of the coating and or improved abrasion resistance of the coating.

The prior art teaches the use of unsaturated vinyl compounds as precursors in plasma deposition processes. However, all of these plasma processes (with the exception of Yamada et al., discussed above), are operated at reduced pressure which requires expensive equipment and processes. For example, the use of reduced pressure plasma processes with vinyl silane precursors can be found in EP469926 A1, US20040062932 A1, EP543634 A1, US20020012755A1, WO1997031034A1, U.S. Pat. No. 4,132,829 A, U.S. Pat. No. 4,096,315, EP299754B1, U.S. Pat. No. 5,904,952A, EP299754A2, and U.S. Pat. No. 4,137,365. Technical publications describing using unsaturated vinyl silanes in reduced pressure plasma deposition processes include K. W. Bieg and K. B. Wischmann, “Plasma-Polymerized Organosilanes as Protective Coatings for Solar Front-Surface Mirrors,” Solar Energy Materials 3(1-2), 301 (1980); U. Hayat, “Improved Process for Producing Well-Adhered/Abrasion-Resistant Optical Coatings on an Optical Plastic Substrate,” Journal of Macromolecular Science, Pure and Applied Chemistry, A31(6), 665 (1994); O. Kolluri, S. Kaplan, and D. Frazier, “Plasma Assisted Coatings for The Plastics Industry,” Surf. Modif. Technol. Proc. Int. Conf, 4th, 783 (1991); P. Laoharojanaphand, T. Lin, and J. Stoffer, “Glow Discharge Polymerization of Reactive Functional Silanes on Poly(methylmethacrylate),” Journal of Applied Polymer Science, 40(3-4), 369 (1990); G. Schammler and J. Springer, “Electroplating onto Inorganic Glass Surfaces. Part I. Surface Modification to Improve Adhesion,” Journal of Adhesion Science and Technology, 9(10), 1307 (1995); S. Shevchuk and Y. Maishev, “Thin Silicon Oxycarbide Thin Films Deposited from Vinyltrimethoxysilane Ion Beams,” Thin Solid Films, 492(1-2), 114 (2005); and T. Wydeven, “Plasma Polymerized Coating for Polycarbonate: Single Layer, Abrasion Resistant, and Antireflection,” Applied Optics, 16(3), 717 (1977).

### SUMMARY OF THE INVENTION

The instant invention is an atmospheric pressure PECVD coating process that provides increased deposition rates for the coating and or improved abrasion resistance of the coating. The technical advance provided by the instant invention is especially useful when thick abrasion resistant coatings are desired and if the plasma coating operation is coupled with another operation, such as an extrusion operation to produce the substrate to be coated.

More specifically, the instant invention is a process for depositing a film coating on an exposed surface of a substrate, the process comprising the steps of: (a) providing a substrate having at least one exposed surface; and (b) flowing a gaseous mixture into an atmospheric pressure plasma that is in contact with at least one exposed surface of said substrate to form a plasma enhanced chemical vapor deposition coating on the substrate, the gaseous mixture comprising an oxidizing gas and a precursor selected from the group consisting of: a vinylalkoxysilane, a vinylalkylsilane, a vinylalkylalkoxysilane, an allyalkoxysilane, an allylalkylsilane, an allylalkylalkoxysilane, an alkenylalkoxysilane, an alkenlyalkylsilane, and an alkenylalkylalkoxysilane, the oxygen content of the gaseous mixture being greater than the equivalent of ten percent molecular oxygen gas by volume.

### BRIEF DESCRIPTION OF THE DRAWINGS

FIG. 1 is a schematic drawing of an apparatus used to practice a process of the instant invention.

### DETAILED DESCRIPTION

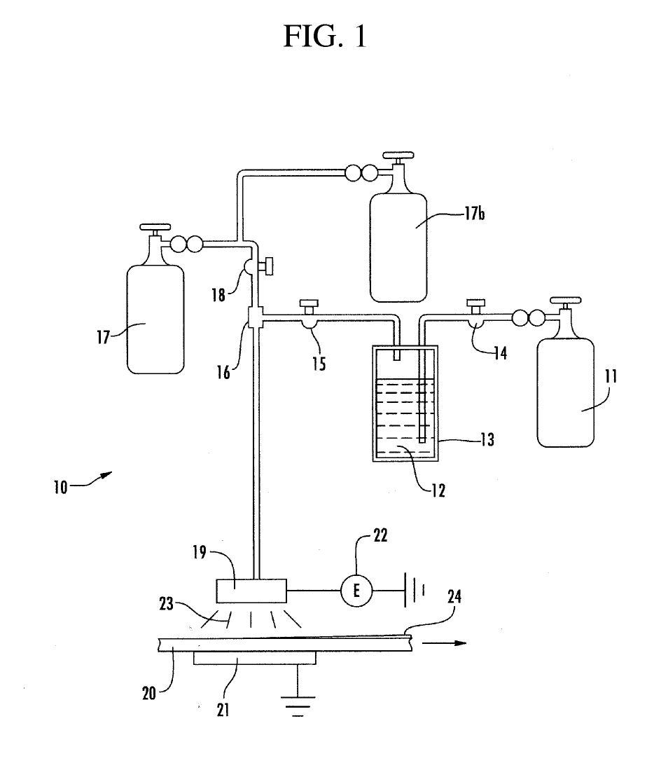

Referring now to FIG. 1, therein is shown a schematic drawing of an apparatus 10 used to practice a preferred embodiment of the instant invention. The apparatus includes a source of carrier gas 11 which is passed through valve 14 and bubbled through a precursor material 12 contained in precursor reservoir 13 to produce a carrier gas saturated with the precursor material which is then passed through valve 15 to tee 16. The apparatus 10 also included a source of oxidant gas 17 and an ionizing gas 17B (which is typically helium) which are flowed through valve 18 to tee 16 and then together with the carrier gas and precursor material to electrode 19, having dimensions of 37 mm wide and 175 mm long. A counterelectrode 21 is spaced from the electrode 19 while the substrate 20 is moved in the direction of the arrow between the electrode 19 and the counterelectrode 21. Electrical power supply 22 in electrical communication with electrode 19 generates a plasma 23 into which the gaseous mixture containing the precursor is flowed from a 0.9 millimeter wide, 17 centimeter long slot in the center of electrode 19. The gap between the surface of the upper electrode and surface of the substrate being coated is 2.0 mm The precursor undergoes reactions in the plasma 23 thereby producing a coating 24 on the substrate 20.

Preferably, the carrier gas 11 is helium at a flow rate of from 0.01 to 150 standard liters per minute (slpm) and more preferably at a flow rate of from 0.05 to 15 slpm. Preferably, the oxidant gas 17 is air or oxygen at a flow rate of from 1 to 60 slpm and more preferably at a flow rate of from 2 to 20 slpm. The ionizing gas helium is flowed at 1 to 150 standard liters per minute, preferably 5 to 30 standard liters per minute. Preferably the power applied to the electrode 19 is in the range of from 1 to 100 Watts per square centimeter and more preferably in the range of from 18 to 37 watts per square centimeter from a square wave DC power supply operating at a frequency less than 100 kHz.

The specific atmospheric pressure plasma enhanced chemical vapor deposition system used in the instant invention is not critical. The plasma can be, for example and without limitation thereto, corona plasma, spark plasma, DC plasma, AC plasma (including RF plasma) or even a microwave generated plasma. The term “atmospheric pressure” means at or near atmospheric pressure and preferably in the open rather than in a pressure controlled chamber.

The gist of the instant invention relates to the use of a specified precursor together with an oxidizing gas in the gaseous mixture that is flowed into the atmospheric pressure plasma, the oxygen content of the gaseous mixture being greater than the equivalent of ten percent molecular oxygen gas by volume. Preferably, such oxygen content of the gaseous mixture is greater than fifteen percent or more by volume such as twenty, twenty five or thirty percent by volume or more. The term “oxidizing gas” means a gas that generates atomic oxygen in the plasma without being a coating precursor. Examples of such oxidizing gases are a gas containing molecular oxygen (i.e., O₂) such as oxygen, and air, and other atomic oxygen-generating gases such as ozone, N₂O, NO, NO₂, N₂O₃ and N₂O₄ and mixtures thereof. Other useful oxidizing gases are carbon dioxide gas, carbon monoxide gas, and hydrogen peroxide gas. If the oxidizing gas molecule contains two oxygen atoms (e.g., NO2), as does molecular oxygen, then this gas must also be used at greater than ten volume percent. If the oxidizing gas molecule contains one oxygen atom (e.g., NO, N₂O), then this gas must be used at greater than 2 times ten volume percent or greater than twenty volume percent. If the oxidizing gas molecule contains three oxygen atoms (e.g., N₂O₃), then this gas must be used at greater than ⅔ times ten volume percent or greater than 6.7 volume percent. If the oxidizing gas molecule contains four oxygen atoms (e.g., N₂O₄), then this gas must be used at greater than ½ times ten volume percent or greater than 5.0 volume percent. In general, if the oxidizing gas molecule contains n oxygen atoms, then the oxidizing gas must be used at a volume percent greater than 10(2/n).

The precursor used in the instant invention comprises or consists essentially of a vinylalkoxysilane, a vinylalkylsilane, a vinylalkylalkoxysilane, an allyalkoxysilane, an allylalkylsilane, an allylalkylalkoxysilane, an alkenylalkoxysilane, an alkenlyalkylsilane, and an alkenylalkylalkoxysilane. Typical examples of such precursors are shown in the following formulas:

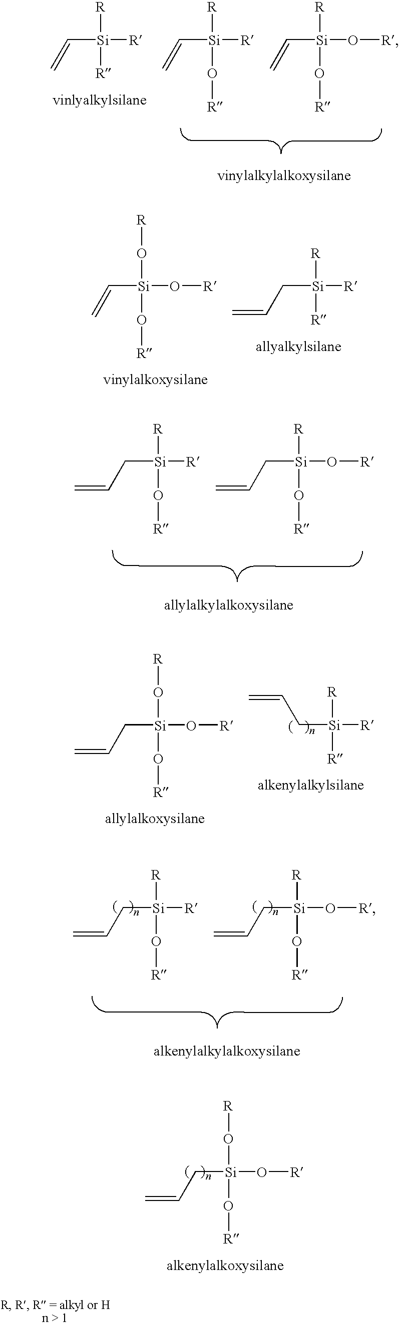

In addition, divinyl, trivinyl, diallyl, triallyl, dialkenyl, and trialkenyl versions of such precursors can also be used.

Preferably, the precursor used in the instant invention comprises or consists essentially of vinyl triethoxysilane, vinyltripropoxysilane, vinyldimethoxyethoxysilane, vinyldiethoxymethoxysilane, vinyldimethylsilane, vinyldimethylsilane, vinylmethyldimethoxysilane, vinylmethyldiethoxysilane, vinyldimethylethoxysilane, allyltrimethoxysilane, 1,3-divinyltetramethyldisiloxane, 1,3-divinyltetraethoxydisiloxane, divinyldimethylsilane, and trivinylmethoxysilane. More preferably, the precursor used in the instant invention comprises or consists essentially of vinyl trimethoxysilane. Surprisingly, a precursor consisting essentially of a mixture of tetramethyldisiloxane and vinyl trimethoxysilane is highly preferred.

When the precursor consists of a mixture of one of the above-mentioned unsaturated materials and a saturated material, then it is preferable that the unsaturated material is vinyl trimethoxysilane and the saturated material is tetramethyldisiloxane. Preferably, the mole ratio of said unsaturated material to said saturated material is 0.25 or higher such as 0.5, 1, 2, 5 or 10 or more. The deposition coating rate obtained using the process of the instant invention can be greater than 1 micrometer per minute such as 1.5 micrometer per minute, 2 micrometers per minute, 3 micrometers per minute or 4 micrometers per minute or more. The hardness of the coating obtained using the process of the instant invention is evidenced by a Taber delta haze after 500 cycles using CS-10F wheels and 500 gram load (ASTM D3489-85(90)) of 4 or less such as less than 3, or less than 2 or less.

The plasma coating operation of the instant invention is readily coupled with a preceding operation to form the substrate, such as injection molding, vacuum molding, compression molding and extrusion. Preferably, the preceding operation to form the substrate is extrusion such as the extrusion of a polycarbonate sheet or film followed by the plasma coating of the polycarbonate sheet or film.

### Comparative Example 1

The apparatus shown in FIG. 1 is assembled. The precursor material 12 is tetramethyldisiloxane (TMDSO) at a reservoir temperature of 20° C. The carrier gas is helium at 0.10 standard liters per minute. The oxidant gas is air at 84 standard liters per minute, and the ionizing gas is helium at 10 standard liters per minute. The electrical power to the electrode is 1.0 kilowatt (18.8 Watts per square centimeter) and the electrodes are controlled with 60° C. cooling water. The substrate is one quarter inch thick polycarbonate sheet moving through the plasma at a rate of 2 meters per minute. The deposition rate of the PECVD coating formed on the polycarbonate sheet is 0.6 micrometers per minute. The coating is tested using the “Taber Test” (ASTM D3489-85(90)) and found to have a delta haze of 5-7.8% after 500 cycles using CS-10F wheels and 500 gram load.

Fourier transform infrared (FTIR) spectroscopy can be used to determine the composition of organosilicon films, as described by S. P. Mukherjee and P. E. Evans in Thin Solid Films, 14, 105 (1972); J. L. C. Fonseca, et. al. in Chem of Mater, 5, 1676, (1993); and P. J. Pai, et al., J. Vac. Sci. Tech. A, 4(3), 689 (1986)). The strong absorbance peak at about 1000 to 1080 wavenumbers is due to the symmetric stretching of Si—O—Si bonds, with higher wavenumber indicating higher degree of oxidation. Absorbance at about 1000 cm⁻¹ indicates a molar Si:O ratio of about 1.0:1.0, while absorbance at about 1080 cm⁻¹ indicates molar Si:O ratio of about 1.0:2.0, with approximately linear relationship. The intensity of the Si—CH₃ symmetric bending absorbance at about 1270 cm⁻¹ indicates the amount of hydrocarbon content. A weak absorbance at about 1270 cm⁻¹ indicates a low amount of hydrocarbon while a strong absorbance at about 1270 cm⁻¹ indicates a high amount of hydrocarbon. Similarly, a weak CH₃ asymmetric stretching absorbance at about 2900 cm⁻¹ indicates low hydrocarbon content while strong absorbance at that frequency indicates high hydrocarbon content.

The polycarbonate is replaced with a potassium bromide (KBr) plate and the above plasma coating is applied then subjected to FTIR analysis. The Si—O—Si symmetric stretching absorbance at 1038 cm⁻¹ indicates an atomic Si:O ratio of 1.0:1.5, or a fairly low degree of oxidation. A strong Si-CH3 stretch at 1270.3 cm⁻¹ and strong absorbance at 2968 cm⁻¹ due to C—H stretching in CH₂ and CH₃ indicates high hydrocarbon content.

### Comparative Example 2

The apparatus shown in FIG. 1 is assembled. The precursor material 12 is tetramethyldisiloxane (TMDSO) at a reservoir temperature of 20° C. The carrier gas is helium at 0.050 standard liters per minute. The oxidant gas is oxygen at 6 standard liters per minute, and the ionizing gas is helium at 15 standard liters per minute. The electrical power to the electrode is 1.0 kilowatt (18.8 Watts per square centimeter) and the electrodes are controlled with 60° C. cooling water. The substrate is one quarter inch thick polycarbonate sheet moving through the plasma at a rate of 2 meters per minute. This is the same precursor as used in COMPARATIVE EXAMPLE 1, but the plasma process conditions are modified to be similar to EXAMPLE 1. The PECVD coating formed on the polycarbonate sheet is soft and oily and thus deposition rate cannot be determined by measuring thickness, nor can Taber abrasion test be performed.

Fourier transform infrared (FTIR) spectroscopy of the coating on a potassium bromide plate shows a strong absorbance peak at about 1045 wavenumbers is due to the symmetric stretching of Si—O—Si bonds, indicating an atomic Si:O ratio of 1.0:1.5, or low degree of oxidation. The strong Si—CH₃ symmetric stretch absorbance at 1263.5 cm⁻¹ and the strong absorbance at 2966 cm⁻¹ due to C—H in CH₂ and CH₃ stretching indicates high hydrocarbon content. This composition is consistent with the physical appearance of the coating.

### Example 1

The apparatus shown in FIG. 1 is assembled. The precursor material 12 is vinyl trimethoxysilane (VTMOS) at a reservoir temperature of 80° C. The carrier gas is helium at 0.75 standard liters per minute. The oxidant gas is oxygen at 6 standard liters per minute, and the ionizing gas is helium at 15 standard liters per minute. The electrical power to the electrode is 1.0 kilowatt (18.8 Watts per square centimeter) centimeter and the electrodes are controlled with 60° C. cooling water. The substrate is one quarter inch thick polycarbonate sheet moving through the plasma at a rate of 2 meters per minute. The deposition rate of the PECVD coating formed on the polycarbonate sheet is 2.1 micrometers per minute. The 1.0 micrometer thick coating is tested using the “Taber Test” (ASTM D3489-85(90)) and found to have a delta haze of 1.1-2.9% after 500 cycles using CS-10F wheels and 500 gram load. This example when compared to the comparative example shows not only the significantly increased coating deposition rate of the method of the instant invention but also the excellent scratch resistance of the coating made according to the method of the instant invention.

The polycarbonate is replaced with a potassium bromide (KBr) plate and the above plasma coating is applied then subjected to FTIR analysis. The Si—O—Si absorbance at 1068 cm⁻¹ indicates a composition that is nearly SiO₂. The lack of hydrocarbon content is confirmed by the near absence of the 2900 cm⁻¹ and 1269 cm⁻¹ peaks. This analysis is consistent with the very hard Taber abrasion results.

In summary, an atmospheric plasma coating using vinyltrimethoxysilane as precursor results in both high deposition rate and a hard coating.

### Example 2

The apparatus shown in FIG. 1 is assembled. The precursor material 12 is vinyl triethoxysilane (VTEOS) at a reservoir temperature of 80° C. The carrier gas is helium at 0.75 standard liters per minute. The oxidant gas is oxygen at 6 standard liters per minute, and the ionizing gas is helium at 15 standard liters per minute. The electrical power to the electrode is 1.0 kilowatt (18.8 Watts per square centimeter) centimeter and the electrodes are controlled with 60° C. cooling water. The substrate is one quarter inch thick polycarbonate sheet moving through the plasma at a rate of 2 meters per minute. The deposition rate of the PECVD coating formed on the polycarbonate sheet is 1.6 micrometers per minute. The coating is not subjected to the quantitative Taber abrasion test, but qualitative testing shows the coating is very hard.

Fourier transform infrared (FTIR) spectroscopy shows symmetric stretching of Si—O-Si bonds absorbance at 1065 cm⁻¹ indicating a composition that is nearly SiO₂, which is very hard.

In summary, an atmospheric plasma coating using vinyltriethoxysilane as precursor results in both high deposition rate and a hard coating.

### Example 3

The apparatus shown in FIG. 1 is assembled. The precursor material 12 is vinylmethyldimethoxysilane (VMDMOS) at a reservoir temperature of 80° C. The carrier gas is helium at 0.75 standard liters per minute. The oxidant gas is oxygen at 6 standard liters per minute, and the ionizing gas is helium at 15 standard liters per minute. The electrical power to the electrode is 1.0 kilowatt (18.8 Watts per square centimeter) centimeter and the electrodes are controlled with 60° C. cooling water. The substrate is one quarter inch thick polycarbonate sheet moving through the plasma at a rate of 2 meters per minute. The deposition rate of the PECVD coating formed on the polycarbonate sheet is 2.6 micrometers per minute. The coating is not subjected to the quantitative Taber abrasion test, but qualitative testing shows the coating is soft.

Fourier transform infrared (FTIR) spectroscopy shows symmetric stretching of Si—O-Si bonds absorbance at 1035 cm⁻¹ indicating an organosiloxane composition that is soft. Although hard coatings are usually desired, there are certain applications where soft coatings are needed.

In summary, an atmospheric plasma coating using vinylmethyldimethoxysilane as precursor results in extremely high deposition rate and a soft coating. Based on the comparative examples, we expect that by adjusting the PECVD process conditions the composition and properties of the coating can be controlled to achieve a more usable coating.

### Example 4

The apparatus shown in FIG. 1 is assembled. The precursor material 12 is vinylmethyldiethoxysilane (VMDEOS) at a reservoir temperature of 80° C. The carrier gas is helium at 0.75 standard liters per minute. The oxidant gas is oxygen at 6 standard liters per minute, and the ionizing gas is helium at 15 standard liters per minute. The electrical power to the electrode is 1.0 kilowatt (18.8 Watts per square centimeter) centimeter and the electrodes are controlled with 60° C. cooling water. The substrate is one quarter inch thick polycarbonate sheet moving through the plasma at a rate of 2 meters per minute. The deposition rate of the PECVD coating formed on the polycarbonate sheet is 2.4 micrometers per minute. The coating is not subjected to the quantitative Taber abrasion test, but qualitative testing shows the coating is soft.

Fourier transform infrared (FTIR) spectroscopy shows symmetric stretching of Si—O-Si bonds absorbance at 1040 cm⁻¹ indicating an organosiloxane composition that is soft.

Although hard coatings are usually desired, there are certain applications where soft coatings are needed.

In summary, an atmospheric plasma coating using vinylmethyldimethoxysilane as precursor results in extremely high deposition rate and a soft coating. Based on the comparative examples, we expect that by adjusting the PECVD process conditions the composition and properties of the coating can be controlled to achieve a more usable coating.

### Example 5

The apparatus shown in FIG. 1 is assembled, but is modified so that two precursors can be delivered simultaneously to the plasma generating electrodes. Precursor material vinyltrimethoxysilane (VTMOS) reservoir temperature is 80° C. and the carrier gas is helium at 0.75 standard liters per minute. Tetramethyldisiloxane (TMDSO) reservoir temperature is 25° C. and the carrier gas is helium at 0.050 standard liters per minute. The oxidant gas is oxygen at 6 standard liters per minute, and the ionizing gas is helium at 15 standard liters per minute. The electrical power to the electrode is 1.0 kilowatt (18.8 Watts per square centimeter) centimeter and the electrodes are controlled with 60° C. cooling water. The substrate is one quarter inch thick polycarbonate sheet moving through the plasma at a rate of 2 meters per minute. The deposition rate of the PECVD coating formed on the polycarbonate sheet is 4.0 micrometers per minute.

The 1.0 micrometer thick coating is tested using the “Taber Test” (ASTM D3489-85(90)) and found to have a delta haze of 1.0-3.0% after 500 cycles using CS-10F wheels and 500 gram load. This example when compared to the comparative example shows not only the significantly increased coating deposition rate of the method of the instant invention but also the excellent scratch resistance of the coating made according to the method of the instant invention.

Fourier transform infrared (FTIR) spectroscopy of the coating on a potassium bromide plate shows the Si—O—Si absorbance at 1079 cm⁻¹ indicating a composition that is essentially SiO₂. The lack of hydrocarbon content is confirmed by the near absence of the 2900 cm⁻¹ and 1269 cm⁻¹ peaks. This analysis is consistent with the very hard Taber abrasion results. In summary, an atmospheric plasma coating using a mixture of vinyltrimethoxysilane and tetramethyldisiloxane as precursors results in both a surprisingly extremely high deposition rate and an extremely hard coating.

Table 1 below is a summary of data selected from the Examples and Comparative Examples wherein the Si—O—Si column relates to the FTIR wavenumber absorbance maxima of the coating in the region from about 1000 cm⁻¹ to about 1080 cm⁻¹ indicates the degree of oxidation of the atomic Si:O ratio in the coating.

TABLE 1

| | | Deposition | | | Taber |
|---|---|---|---|---|---|
| | | rate, | | | Delta haze |
| | | micrometers | Si—O—Si, | | 500 cycles |
| | Precursor | per minute | 1/cm | Comments | 1 micron coating |
| COMPARATIVE | Tetramethyldisiloxane | 0.6 | 1038 | Hard | 5.0-7.8 |
| EXAMPLE 1 | (TMDSO) | | | | |
| COMPARATIVE | Tetramethyldisiloxane | — | 1045 | Oily | — |
| EXAMPLE 2 | (TMDSO) | | | | |
| EXAMPLE 1 | Vinyltrimethoxysilane | 2.1 | 1068 | Very hard | 1.1-2.9 |
| | (VTMOS) | | | | |
| EXAMPLE 2 | Vinyltriethoxysilane | 1.6 | 1065 | Hard | — |
| | (VTEOS) | | | | |
| EXAMPLE 3 | Vinylmethyldimethoxysilane | 2.6 | 1035 | Soft and | — |
| | (VMDMOS) | | | hazy | |
| EXAMPLE 4 | Vinylmethyldiethoxysilane | 2.4 | 1040 | Soft and | — |
| | (VMDEOS) | | | hazy | |
| EXAMPLE 5 | Vinyltrimethoxysilane | 4.0 | 1079 | Extremely | 1.0-3.0 |
| | (VTMOS) + | | | hard | |
| | Tetramethyldisiloxane | | | | |
| | (TMDSO) | | | | |

### CONCLUSION

While the instant invention has been described above according to its preferred embodiments, it can be modified within the spirit and scope of this disclosure. This application is therefore intended to cover any variations, uses, or adaptations of the instant invention using the general principles disclosed herein. Further, the instant application is intended to cover such departures from the present disclosure as come within the known or customary practice in the art to which this invention pertains and which fall within the limits of the following claims.

1. A process for depositing a film coating on an exposed surface of a substrate, the process comprising the steps of: (a) providing a substrate having at least one exposed surface; and (b) flowing a gaseous mixture into an atmospheric pressure plasma that is in contact with at least one exposed surface of said substrate to form a plasma enhanced chemical vapor deposition coating on the substrate, the gaseous mixture comprising an oxidizing gas and a precursor selected from the group consisting of: a vinylalkoxysilane, a vinylalkylsilane, a vinylalkylalkoxysilane, an allyalkoxysilane, an allylalkylsilane, an allylalkylalkoxysilane, an alkenylalkoxysilane, an alkenlyalkylsilane, an alkenylalkylalkoxysilane and mixtures thereof, the oxygen content of the gaseous mixture being greater than the equivalent of fifteen percent molecular oxygen gas by volume.

2. The process of claim 1, wherein the gaseous mixture comprises a precursor selected from the group consisting of: vinyl triethoxysilane, vinyltripropoxysilane, vinyl dimethoxyethoxysilane, vinyldiethoxymethoxysilane, vinyldimethylsilane, vinyldimethylsilane, vinylmethyldimethoxysilane, vinylmethyldiethoxysilane, vinyldimethylethoxysilane, allyltrimethoxysilane, 1,3-divinyltetramethyldisiloxane, 1,3-divinyltetraethoxydisiloxane, divinyldimethylsilane, and trivinylmethoxysilane.

3. The process of claim 1, wherein the precursor consists essentially of a vinylalkoxysilane, vinylalkylsilane, vinylalkylalkoxysilane, allyalkoxysilane, allylalkylsilane, allylalkylalkoxysilane, alkenylalkoxysilane, alkenlyalkylsilane, alkenylalkylalkoxysilane, or a mixture thereof.

4. The process of claim 1, wherein the precursor consists essentially of vinyl triethoxysilane, vinyltripropoxysilane, vinyl dimethoxyethoxysilane, vinyldiethoxymethoxysilane, vinyldimethylsilane, vinyldimethylsilane, vinylmethyldimethoxysilane, vinylmethyldiethoxysilane, vinyldimethylethoxysilane, allyltrimethoxysilane, 1,3-divinyltetramethyldisiloxane, 1,3-divinyltetraethoxydisiloxane, divinyldimethylsilane, trivinylmethoxysilane, or a mixture thereof.

5. The process of claim 1, wherein the precursor consists essentially of vinyl trimethoxysilane.

6. The process of claim 1, wherein the gaseous mixture comprises a mixture of vinyl trimethoxysilane and tetramethyldisiloxane.

7. The process of claim 1, the process further comprising the step of producing the substrate by a substrate production process selected from the group consisting of: injection molding, vacuum molding, compression molding, and extrusion.

8. The process of claim 7, wherein the substrate production process is extrusion.

9. The process of claim 1, wherein the oxidizing gas is selected from the group consisting of air, oxygen, ozone, N₂O, NO, NO₂, N₂O₃, N₂O₄ and mixtures thereof.

10. The process of claim 1, wherein the plasma enhanced chemical vapor deposition coating is characterized by an abrasion resistance when subjected to a Taber test using CS-10F wheels and 500 gram load following ASTM D3489-85(90) that exhibits increase in haze of less than about 5% after 500 cycles.

11. The process of claim 1, wherein the plasma enhanced chemical vapor deposition coating is deposited at a rate greater than about 2 micrometers per minute.

12. The process of claim 1, wherein the plasma enhanced chemical vapor deposition coating is characterized by having a thickness greater than about one micrometer.

13. The process of claim 1, wherein the oxygen content of the gaseous mixture is greater than the equivalent of twenty-five percent molecular oxygen gas by volume.

14. The process of claim 1, wherein the precursor consists essentially of the vinylalkoxysilane, vinylalkylsilane, vinylalkylalkoxysilane, allyalkoxysilane, allylalkylsilane, allylalkylalkoxysilane, alkenylalkoxysilane, alkenlyalkylsilane, or alkenylalkylalkoxysilane.
